(19) United States
(12) Patent Application Publication
(10) Pub. No.: US 2026/0344502 A1
(43) Pub. Date: Oct. 29, 2026

(54) Semiconductor Device and Methods of Manufacture

(71) Applicant: Taiwan Semiconductor Manufacturing Co., Ltd., Hsinchu (TW)

(72) Inventors: Sheng-Han Tsai, Hsinchu (TW); Tsung-Yu Chen, Hsinchu (TW); Hong-Yu Guo, Hsinchu (TW); Tsung-Shu Lin, New Taipei City (TW)

(21) Appl. No.: 19/727,084

(22) Filed: Jul. 1, 2026

Related U.S. Application Data
(62) Division of application No. 18/352,363, filed on Jul. 14, 2023.

(51) Int. Cl. H10W 74/10; H10P 72/70; H10W 74/01; H10W 74/43; H10W 74/47; H10W 90/00; H10W 72/00; H10W 72/90; H10W 80/00

(52) U.S. Cl. CPC H10W 74/121; H10P 72/74; H10W 74/019; H10W 74/43; H10W 74/47; H10W 90/00; H10P 72/744; H10W 72/01938; H10W 72/0198; H10W 72/953; H10W 80/312; H10W 80/327; H10W 90/792; H10W 90/794

(57) ABSTRACT

Semiconductor device and methods of manufacture are provided. In an embodiment, the a semiconductor device may include a first semiconductor die; an oxide layer on the first semiconductor die, wherein the first semiconductor die has a first top surface opposite the oxide layer; a first insulating material encapsulating the first semiconductor die and the oxide layer, wherein the first insulating material has a second top surface planar with the first top surface; and a first polymer buffer disposed between a sidewall of the first semiconductor die and a sidewall of the oxide layer, wherein the first polymer buffer has a third top surface planar with both the first top surface and the second top surface.

### PRIORITY CLAIM AND CROSS-REFERENCE

This application is a divisional of U.S. Patent Application No. 18/352,363, filed on Jul. 14, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6A, 6B, 7, 8, 9, 10, 11, and 12, illustrate varying views of intermediate steps of manufacturing a semiconductor package in accordance with some embodiments.

FIGS. 13, 14, 15A, 15B, 16, 17A, 17B, 18, 19, 20, 21, 22 and 23 illustrate cross-sectional and top-down plan views of steps for forming an integrated circuit package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, buffer structures are formed surrounding semiconductor dies in integrated circuit packages in order to reduce the risk of corner crack propagation from structural stresses caused during the manufacture of the integrated circuit package. By forming buffer structures surrounding the individual semiconductor dies with the buffer structure being less brittle than a gapfill material (also referred to as an insulating material) used between the semiconductor dies, the risk of corner crack propagation may be reduced and non-bond stress may be reduced by about thirty percent. The inclusion of the buffer structure may help improve the functionality and integrity of stacked dies from the stress absorption provided by the buffer structure.

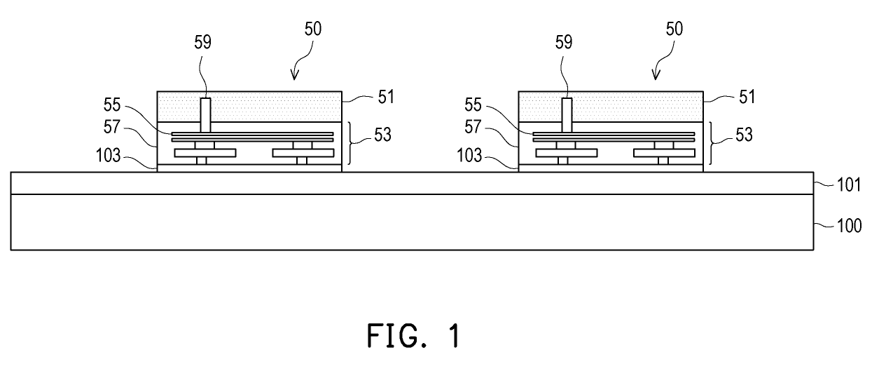

FIG. 1 illustrates a cross-sectional view of a one or more first integrated circuit dies 50 bonded to a first bonding layer 101 of a first carrier substrate 100 in accordance with some embodiments. In accordance with some embodiments, the first carrier substrate 100 comprises silicon, or the like. The first bonding layer 101 may comprise an oxide, such as silicon oxide, silicon oxynitride, the like, or a combination thereof, and may be formed by high density plasma chemical vapor deposition (HDP-CVD), a flowable CVD (FCVD) (e.g., a CVD-based material deposition in a remote plasma system and post curing to make it convert to the oxide), atomic layer deposition, (ALD), physical vapor deposition (PVD), the like, or a combination thereof. Other oxide materials formed by any acceptable process may be used to form the first bonding layer 101 over the first carrier substrate 100.

In accordance with some embodiments, the first integrated circuit die 50. may be a bare chip semiconductor die (e.g., an unpackaged semiconductor die). For example, the first integrated circuit die 50 may be a logic die (e.g., AP, central processing unit, microcontroller, etc.), a memory die (e.g., DRAM die, HBC, SRAM die, wideIO memory die, mRAM die, rRAM) die, etc.), a power management die (e.g., PMIC dies), a RF die, a sensor die, a MEMS die, a signal processing die (e.g., DSP die), a front-end die (e.g., AFE die), a biomedical die, or the like.

The first integrated circuit die 50 may be processed according to applicable manufacturing processes to form integrated circuits in the first integrated circuit die 50. For example, the first integrated circuit die 50 may each include a first semiconductor substrate 51, such as silicon, doped or undoped, or an active layer of a semiconductor-on-insulator (SOI) substrate. The first semiconductor substrate 51 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Devices, such as transistors, diodes, capacitors, resistors, or the like, may be formed in and/or on the first semiconductor substrate 51 and may be interconnected by a first interconnect structure 53, which comprises first metallization patterns 55 (e.g., conductive lines and vias) in one or more first interconnect dielectric layers 57 to form one or more integrated circuits. The first interconnect dielectric layers 57 may comprise silicon oxide, silicon nitride, silicon oxynitride, a polymer, or the like and be deposited by PVD, CVD, ALD, or the like. The first metallization patterns 55 may be conductive features formed in the first interconnect dielectric layers 57 by damascene processes, for example.

Additionally, the first integrated circuit die 50 may include one or more through silicon vias (TSVs) 59 that extend into the first semiconductor substrate 51 of the first integrated circuit die 50 so as to provide a quick passage of data signals. In an embodiment the TSVs 59 may be formed by initially forming TSV openings into the first semiconductor substrate 51 (e.g., prior to formation of the active devices). The TSV openings may be formed by applying and developing a suitable photoresist (not shown), and removing portions of the first semiconductor substrate 51 that are exposed to the desired depth. The TSV openings may be formed so as to extend into the first semiconductor substrate 51 at least further than the active devices formed within and/or on the first semiconductor substrate 51, and may extend to a depth greater than the eventual desired height of the first semiconductor substrate 51. Once the TSV openings have been formed within the first semiconductor substrate 51, the TSV openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may alternatively be used.

Once the liner has been formed along the sidewalls and bottom of the TSV openings, a barrier layer (also not independently illustrated) may be formed and the remainder of the TSV openings may be filled with first conductive material. The first conductive material may comprise copper, although other suitable materials such as aluminum, alloys, doped polysilicon, combinations thereof, and the like, may alternatively be utilized. The first conductive material may be formed by electroplating copper onto a seed layer (not shown), filling and overfilling the TSV openings. Once the TSV openings have been filled, excess liner, barrier layer, seed layer, and first conductive material outside of the TSV openings may be removed through a planarization process such as chemical mechanical polishing (CMP), although any suitable removal process may be used.

In accordance with some embodiments, a second bonding layer 103 may be deposited over what may be referred to as an active side or front side of the first integrated circuit die 50. The active side/front side of the first integrated circuit die 50 may refer to a side of the first semiconductor substrate 51 on which the active devices are formed. The back side of the first integrated circuit die 50 may refer to a side of the first semiconductor substrate 51 opposite the active side/front side. In some embodiments, the second bonding layer 103 may be an oxide, such as silicon oxide, silicon oxynitride, the like, or a combination thereof, and may be formed by HDP-CVD, FCVD, CVD, ALD, PVD, the like, or a combination thereof. Other oxide materials formed by any acceptable process may be used to forming the second bonding layer 103 over the first integrated circuit die 50.

In an embodiment, the one or more first integrated circuit dies 50 may be bonded to the first carrier substrate 100 through a first dielectric-to-dielectric bonding process (e.g., oxide-to-oxide bonding) forming a first dielectric-to dielectric bond (e.g., an oxide-to-oxide bond). The first dielectric-to-dielectric bond may be initiated by activating the first bonding layer 101 and/or the second bonding layer 103 followed by applying pressure, heat and/or other bonding process steps to join the first bonding layer 101 to the second bonding layer 103 surfaces. The activating the first bonding layer 101 and the second bonding layer 103 may be performed using, e.g., a dry treatment, a wet treatment, a plasma treatment, exposure to H₂, exposure to N₂, exposure to O₂, combinations of these, or the like. In embodiments where a wet treatment is used, an RCA cleaning process may be used, for example. The activating assists in the first dielectric-to-dielectric bonding of the first bonding layer 101 and the second bonding layer 103 by, e.g., allowing the use of lower pressures and temperatures in subsequent first dielectric-to-dielectric bonding processes. Through the treatment, the number of OH groups at surface(s) of the first bonding layer 101 and/or the second bonding layer 103 increases. After surfaces of the first bonding layer 101 and/or the second bonding layer 103 are activated, the first bonding layer 101 and the second bonding layer 103 may be contacted together at a relatively low temperature (e.g., room temperature) to form weak bonds. Subsequently, an annealing is performed to strengthen the weak bonds and form a first dielectric-to-dielectric bond. During the annealing, the H of the OH bonds is outgassed, thereby forming Si-O-Si bonds between the first bonding layer 101 and the second bonding layer 103, thereby strengthening the bonds.

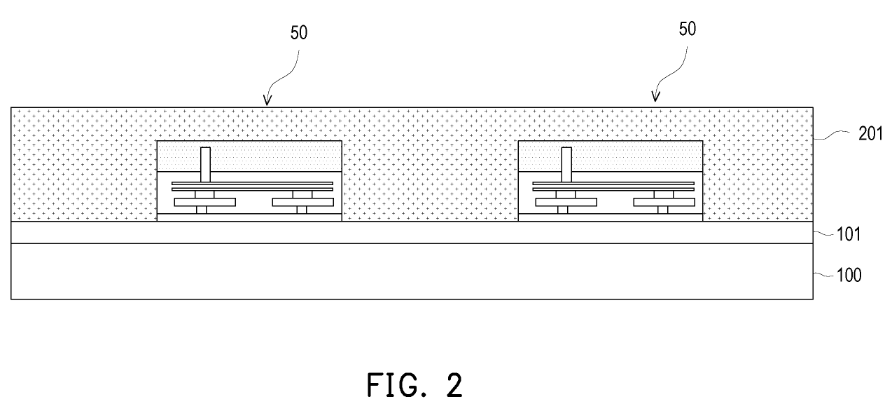

FIG. 2 illustrates a cross-sectional view of a first buffer material 201 being formed over the first carrier substrate 100 covering the one or more first integrated circuit dies 50 in accordance with some embodiments. In an embodiment, the first buffer material 201 may comprise a polymer such as, a photosensitive polymer, a polyimide, or the like. In an embodiment, the first buffer material 201 may comprise HD4100, HD8820, Fuji LTC9320-E07, Toray LT-S8300A, HD7100, Asahi BL301, Benzocyclobutene (BCB) base material, Polybenzoxazoles(PBO) base material, the like, or a combination thereof. In an embodiment, the first buffer material 201 may be formed by spin coating the first buffer material 201 over the first carrier substrate 100 and the one or more first integrated circuit dies 50. However, any suitable material may be used for forming the first buffer material 201. In accordance with some embodiments, the first buffer material 201 may have a first toughness in a range of 10 J/m³ to 1,000 J/m³. If the first buffer material 201 has a toughness less than the first toughness than the first buffer material 201 may be too brittle and have an inadequate risk of crack propagation. If the first buffer material 201 has a toughness greater than the first toughness than the first buffer material 201 may not be rigid enough to provide adequate support for subsequent processing steps performed over the first buffer material 201.

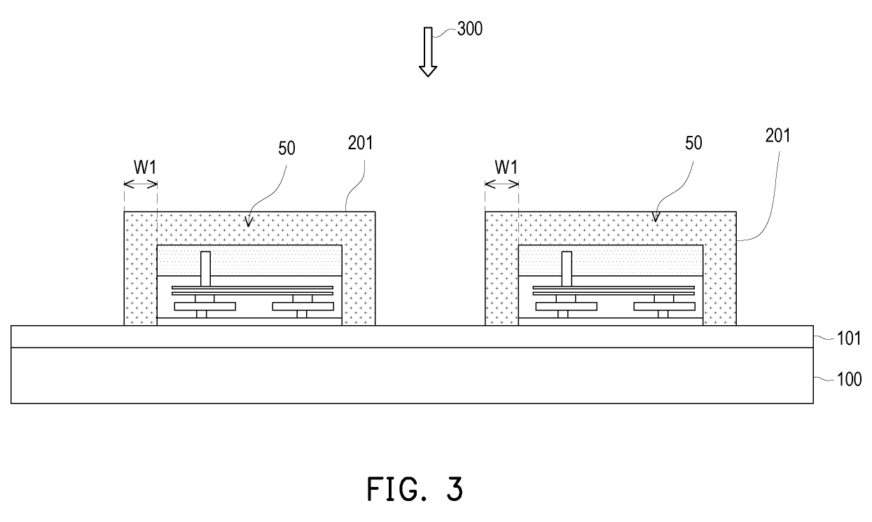

FIG. 3 illustrates a cross-sectional view of a patterning process 300 of the first buffer material 201 to remove excess portions of the first buffer material 201 around the one or more first integrated circuit dies 50 over the first carrier substrate 100 in accordance with some embodiments. In an embodiment, the first buffer material 201 may be a photo-sensitive material such as any of the materials described above that may be patterned using a lithography mask. For example, the first buffer material 201 may be patterned by exposing the first buffer material 201 to light through the lithography mask and developing the first buffer material 201 after the exposure to remove exposed/unexposed portions of the first buffer material 201 depending on whether the first buffer material 201 is a positive or negative photosensitive material. In accordance with some embodiments, following the patterning process 300 excess portions of the first buffer material 201 have been removed from over the first carrier substrate 100 with remaining portions of the first buffer material 201 surrounding sidewalls and a top surface of the one or more first integrated circuit dies 50. In an embodiment, the patterning process 300 is performed so that the remaining portions of the first buffer material 201 have a first width W1 surrounding the sidewalls of each first integrated circuit die 50 in a range of 1 micron to 30 microns. If the first width W1 of the first buffer material 201 is less than 1 micron than the first buffer material 201 may not be able to adequately absorb stresses incurred during subsequent manufacturing processes in order to adequately reduce risk of non-bond crack propagation (e.g., stresses incurred from forming bonding additional devices over the first integrated circuit dies 50). If the first width W1 of the first buffer material 201 is greater than 30 microns, then the first buffer material 201 may not provide adequate structural support for the first integrated circuit dies 50 during subsequent manufacturing processes.

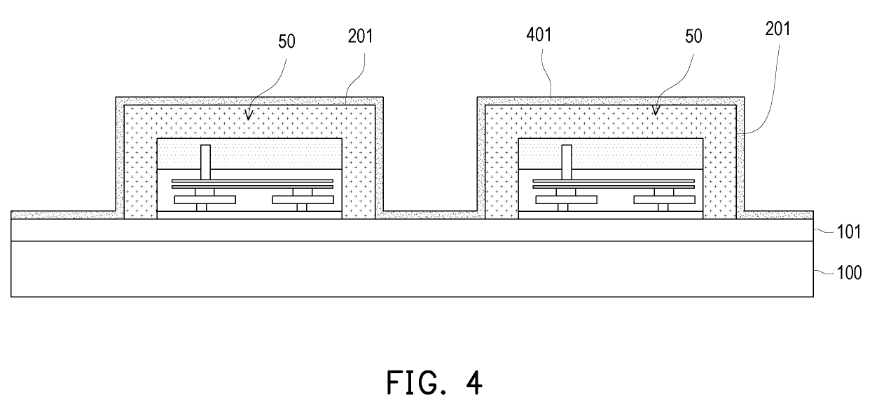

FIG. 4 illustrates a cross-sectional view of a formation of a first barrier layer 401 over the first carrier substrate 100 and over the first buffer material 201 covering the one or more first integrated circuit dies 50 in accordance with some embodiments. In an embodiment, the first barrier layer 401 comprises silicon nitride, or the like. In an embodiment the first barrier layer 401 may be deposited using a suitable deposition process such as CVD, ALD, HDPCVD, combinations of these, or the like. However, any suitable material and deposition process may be utilized for forming the first barrier layer 401.

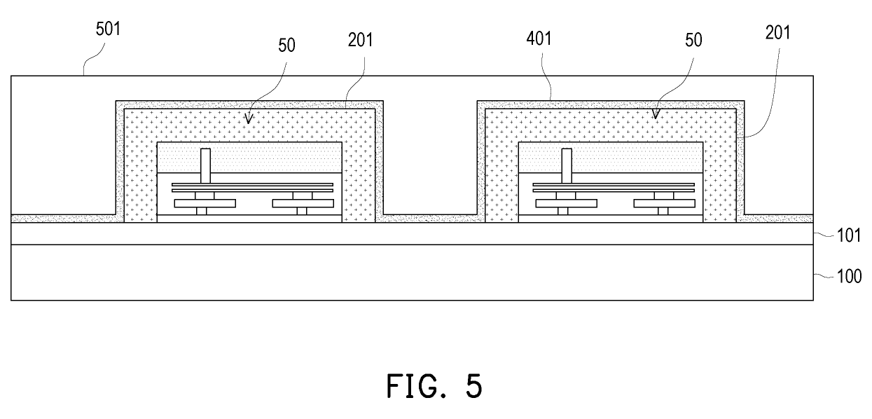

FIG. 5 illustrates a cross-sectional view of a first gapfill material 501 (also referred to as an insulating material) over the first barrier layer 401 in accordance with some embodiments. In accordance with some embodiments, the first gapfill material 501 may be an oxide such as silicon oxide (e.g., silicon dioxide), or the like. The first gapfill material 501 may be formed by spin-coating, HDPCVD, or the like. In some embodiments the first gapfill material 501 is formed to over fill the one or more first integrated circuits 50 and fill any gaps in between the one or more first integrated circuits 50. In accordance with some embodiments, the first gapfill material 501 has a second toughness less than the first toughness. In such embodiments the first gapfill material 501 is more brittle than the first buffer material 201 (e.g., the first buffer material 201 may be more flexible and may absorb more stress before deforming than the first gapfill material 501). In some embodiments, the first gapfill material 501 may also have a greater geometric stiffness than the first buffer material 201. In some embodiments, the geometric stiffness of the first gapfill material 501 provides structural stability for subsequent processing steps performed over the first gapfill material 501. In some embodiments, where the geometric stiffness of the first gapfill material 501 is greater than the geometric stiffness of the first buffer material 201 the geometric stiffness of the first gapfill material 501 may help provide additional rigidity to compensate for the flexibility of the first buffer material 201.

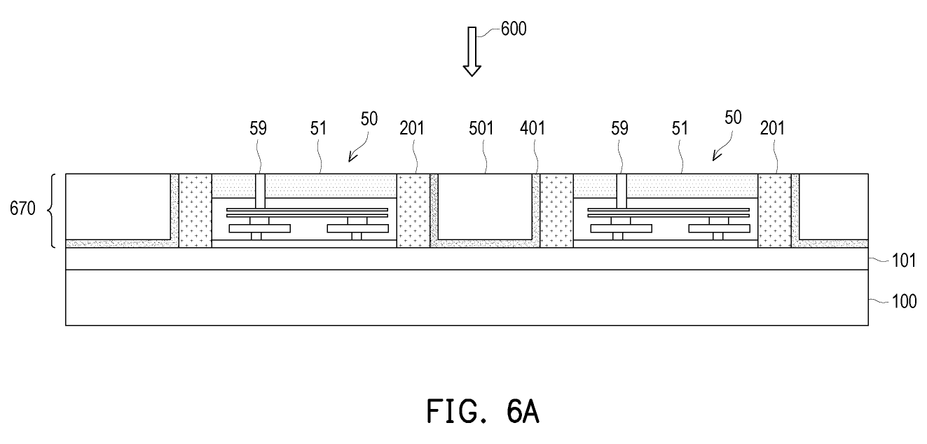

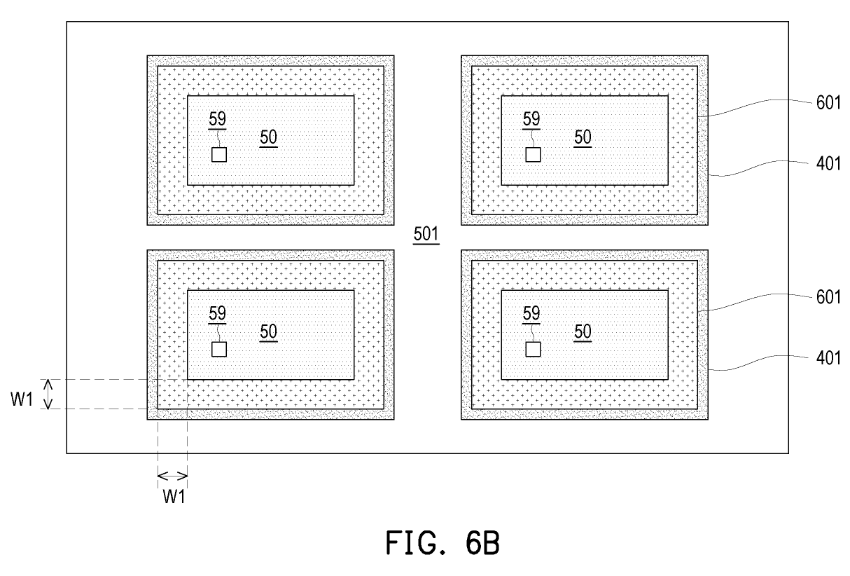

FIG. 6A illustrates a cross-sectional view of a first planarization process 600 performed on the first gapfill material 501, the first barrier layer 401, the first buffer material 201 and the one or more first integrated circuit dies 50 in accordance with some embodiments. In an embodiment, the first planarization process 600 may be a chemical-mechanical polish (CMP) planarization process. In an embodiment the first planarization process 600 removes portions of the first gapfill material 501, portions of the first barrier layer 401, portions of the first buffer material 201, and portions of the first semiconductor substrate 51 of the one or more first integrated circuit dies 50. In some embodiments, the first planarization process 600 further exposes the TSVs 59 within the first semiconductor substrates 51 of the one or more first integrated circuit dies 50. Further, in an embodiment, following the first planarization process 600 a portion of the first buffer material 201 covering each of the one or more first integrated circuit dies 50 is removed forming a first buffer structure 601 that fully surrounds each of the sidewalls of the first integrated circuit die 50. In an embodiment, the first buffer structure 601 has the first width W1 and may maintain the same toughness as the first buffer material 201 because toughness is a material property associated with the material of the first buffer structure 601. Additionally, after the first planarization process 600, the first gapfill material 501, the first barrier layer 401, the first integrated circuit die 50 and the first buffer structure 601 all share a first planar top surface. Further, the first planarization process 600 resulting in the formation of the first buffer structure 601 establishes a first bottom device layer 670 upon which subsequent layers of integrated circuit dies and associated structures may be formed upon.

FIG. 6B illustrates a top-down plan view following the first planarization process 600 performed on the first gapfill material 501, the first barrier layer 401, the first buffer material 201, and the one or more first integrated circuit dies 50 resulting in the first buffer structure 601in accordance with some embodiments. As illustrated by FIG. 6B, each of the first buffer structures 601 fully encircles each of the first integrated circuit dies 50, with each of the first buffer structure 601 being in direct physical contact with each of the first integrated circuit dies 50. The first buffer structures 601 also each have the first width W1 measured from sidewalls of the first integrated circuit dies 50 to an exterior sidewall of the first buffer structures 601. Further, each of the first barrier layers 401 is in direct contact with sidewalls of each of the first buffer structures 601 and fully encircles each of the first buffer structures 601. The first gapfill material 501 fills remaining gaps between the different first integrated circuit dies 50 and the associated first buffer structures 601 and the associated first barrier layer 401.

In an embodiment, advantages are achieved through the first buffer structure 601 by providing for a structure spanning the height of the integrated circuit dies 50 adjacent to corners of the integrated circuit dies 50 that are capable of absorbing stress and strain that may occur from subsequent processing steps. The increased toughness of the first buffer structure 601 encircling the integrated circuit dies 50 may allow for strain absorption reducing the risk of corner crack propagation at the corners of the first integrated circuit dies 50 or non-bond formation along the edges of the first integrated circuit dies 50. The geometric stiffness provided by the first gapfill material 501 may supplement the first buffer structures 601 absorption abilities by providing rigidity to the structure to adequately support overlying device layers.

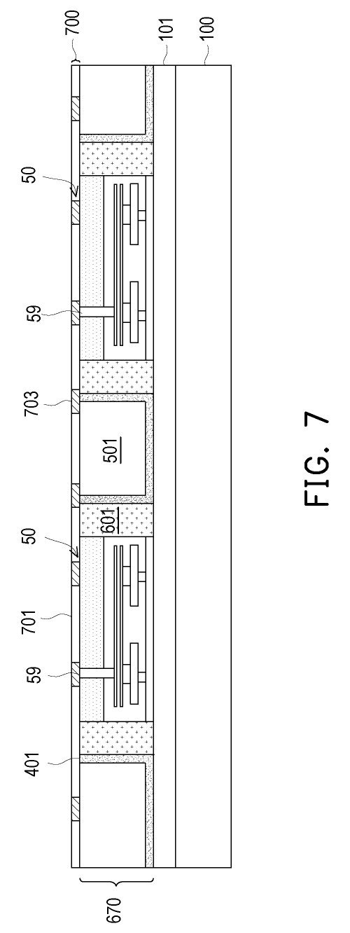

FIG. 7 illustrates a cross-sectional view of the formation of a third bonding layer 700 over the first planar top surface of the first bottom device layer 670 in accordance with some embodiments. In an embodiment, the third bonding layer 700 may comprise a first dielectric layer 701 and first bond pads 703 embedded within the first dielectric layer 701. In some embodiments, the first bond pads 703 may comprise a conductive material such as copper, or the like. Some of the first bond pads 703 may be physically and electrically coupled to the TSVs 59. In an embodiment, the first dielectric layer 701 may comprise a silicon-containing dielectric material such as silicon oxide, silicon nitride, silicon oxynitride, or the like, and the first dielectric layer 701 may be deposited using a suitable deposition process such as CVD, PVD, ALD, HDPCVD, combinations of these, or the like. The first bond pads 703 may be formed within the first dielectric layer 701 or formed prior to the first dielectric layer 701 using any suitable process, such as a damascene process, electroplating, or the like.

For example, in an embodiment in which the first dielectric layer 701 is formed prior to the formation of the first bond pads 703, openings corresponding to the location of the first bond pads 703 may be formed in the first dielectric layer 701 using a combination of photolithography and etching processes. Once the openings have been formed within the first dielectric layer 701, the openings may be filled with a seed layer (not separately illustrated) and a plate metal to form the first bond pads 703 within the first dielectric layer 701. The seed layer may be blanket deposited over top surfaces of the first dielectric layer 701 and the exposed conductive portions of the underlying layers and sidewalls of the openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like.

As another example, in an embodiment in which the first dielectric layer 701 is formed after the formation of the first bond pads 703, a seed layer may be blanket deposited over the first integrated circuit dies 50, the first buffer structure 601, the first barrier layer 401, and the first gapfill material 501. A photoresist (not separately illustrated) may be formed and patterned to define a layout of the first bond pads 703, and a plating process may be applied to form a plate metal in the openings of the photoresist. Subsequently, the photoresist and portions of the seed layer not covered by the plate metal may be removed, with remaining portions of the seed layer and the plate metal forming the first bond pads 703. The first dielectric layer 701 is then deposited around the first bond pads 703.

Optionally, a planarization step may then be performed to level a top surface of the third bonding layer 700 and the first bond pads 703 such that the third bonding layer 700 has a high degree of planarity with the first bond pads 703. Other materials and formation methods are also possible.

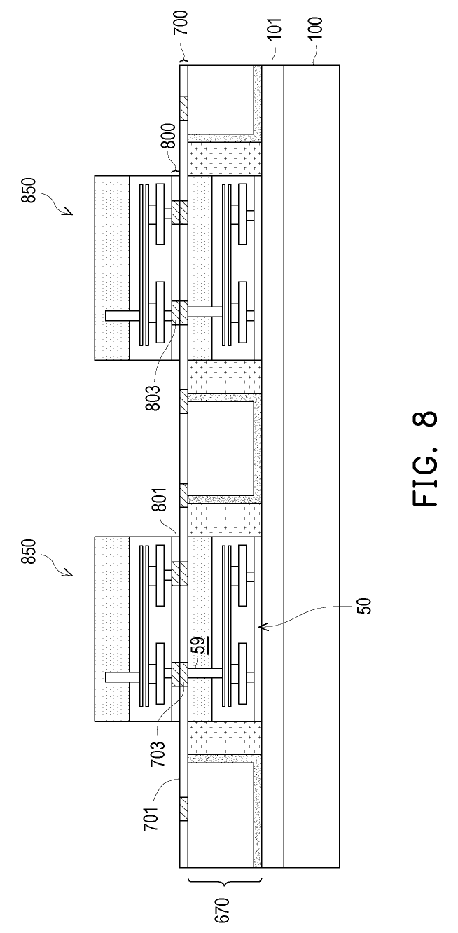

FIG. 8 illustrates a cross-sectional view of the bonding of second integrated circuit dies 850 to the third bonding layer 700. In an embodiment, the second integrated circuit dies 850 may be substantially similar to the first integrated circuit dies 50. In some embodiments, a fourth bonding layer 800 is formed over an active side/front side of the second integrated circuit die 850. The fourth bonding layer 800 may comprise a second dielectric layer 801 and second bond pads 803 embedded within the second dielectric layer 801. In an embodiment, the second dielectric layer 801 and the second bond pads 803 may be formed of similar materials and in a similar manner as the first dielectric layer 701 and the first bond pads 703, respectively.

In accordance with some embodiments, the second integrated circuit dies 850 are bonded over the first integrated circuit dies 50 by bonding the third bonding layer 700 to the fourth bonding layer 800 by a dielectric-to-dielectric and metal-to-metal bonding process performed between the third bonding layer 700 and the fourth bonding layer 800. In some embodiments, the dielectric-to-dielectric bonding process forms a direct bond (e.g. an oxide-to-oxide bond) between the first dielectric layer 701 and the second dielectric layer 801. Further, the metal-to-metal bonding process may directly bond the first bond pads 703 of the third bonding layer 700 to the second bond pads 803 of the fourth bonding layer 800 through direct metal-to-metal bonding. Thus, electrical connection between the first integrated circuit die 50 and the second integrated circuit die 850 may be provided by the physical connection of the first bond pads 703 to the second bond pads 803, where some of the second bond pads 803 are electrically coupled to the first metallization patterns 55 within the second integrated circuit dies 850. The dielectric-to-dielectric bonding process may start with applying a surface treatment to either or both of the first dielectric layer 701 and the second dielectric layer 801 facilitating a dielectric-to-dielectric bond between the first dielectric layer 701 and the second dielectric layer 801 (e.g. a such as an oxide-to-oxide bond). The surface treatment may include a plasma treatment. The plasma treatment may be performed in a vacuum environment. After the plasma treatment, the surface treatment may further include a cleaning process (e.g., a rinse with deionized water, or the like) that may be applied to either or both of the first dielectric layer 701 and the second dielectric layer 801. The dielectric-to-dielectric and metal-to-metal bonding process may then proceed to aligning the second bond pads 803 of the fourth bonding layer 800 to the first bond pads 703 of the third bonding layer 700. Next, the dielectric-to-dielectric and metal-to-metal bonding process includes a pre-bonding step, during which the fourth bonding layer 800 of the second integrated circuit die 850 is put in contact with the third bonding layer 700. The pre-bonding may be performed at room temperature (e.g., between about 21°C and about 25°C). The dielectric-to-dielectric and metal-to-metal bonding process continues with performing an anneal, for example, at a temperature between about 150°C and about 400°C for a duration between about 0.5 hours and about 3 hours, so that the first bond pads 703 (e.g., copper) and the second bond pads 803 (e.g., copper) inter-diffuses to each other, and hence the direct metal-to-metal bonding is formed.

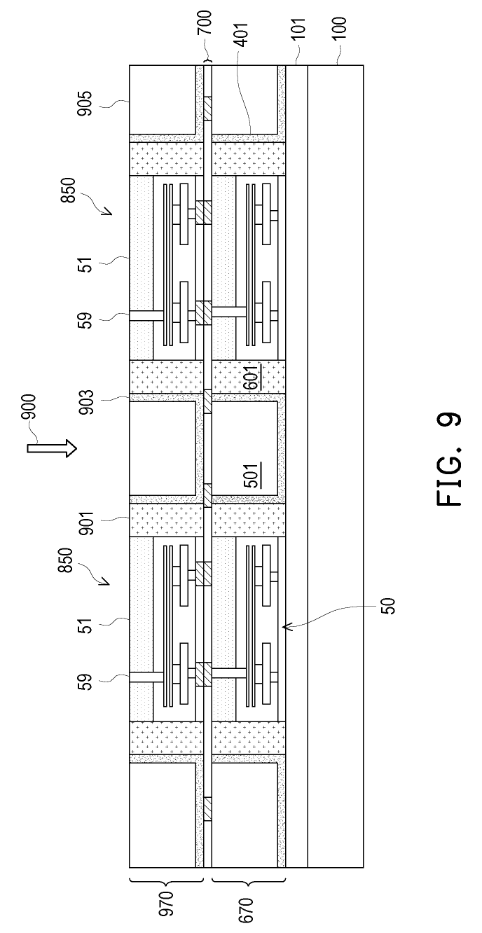

FIG. 9 illustrates a cross-sectional view of a formation of a second buffer structure 901, a second barrier layer 903 and a second gapfill material 905 encircling the second integrated circuit dies 850. In accordance with some embodiments, following the formation of the second buffer structure 901, the second barrier layer 903, and the second gapfill material 905, a second planarization process 900 may be performed revealing the TSVs 59 of the second integrated circuit dies 850 through the first semiconductor substrate 51 of the second integrated circuit dies 850. Further, in some embodiments, the second planarization process may planarize a top surface of the second integrated circuit dies 850, the TSVs 59 of the second integrated circuit dies 850, the second buffer structure 901, the second barrier layer 903 and the second gapfill material 905, such that the top surfaces of the recited features are coplanar. In an embodiment, the formation of the second buffer structure 901, the second barrier layer 903 and the second gapfill material 905, as well as the second planarization process 900 may be processed in a substantially similar manner as previously discussed with respect to the first buffer structure 601, the first barrier layer 401, the first gapfill material 501, and the first planarization process 600, respectively, and details are not repeated herein for simplicity. In an embodiment, the performed processes are performed over the third bonding layer 700 as opposed to the first bonding layer 101 of the first carrier substrate 100. Thus, a first middle device layer 970 comprising the second integrated circuit dies 850, the second buffer structure 901, the second barrier layer 903, and the second gapfill material 905 may be formed. Further, it should be noted that a cycle forming the first middle device layer 970 may be repeated as many times as suitable for forming a desired number of the stacked device layers.

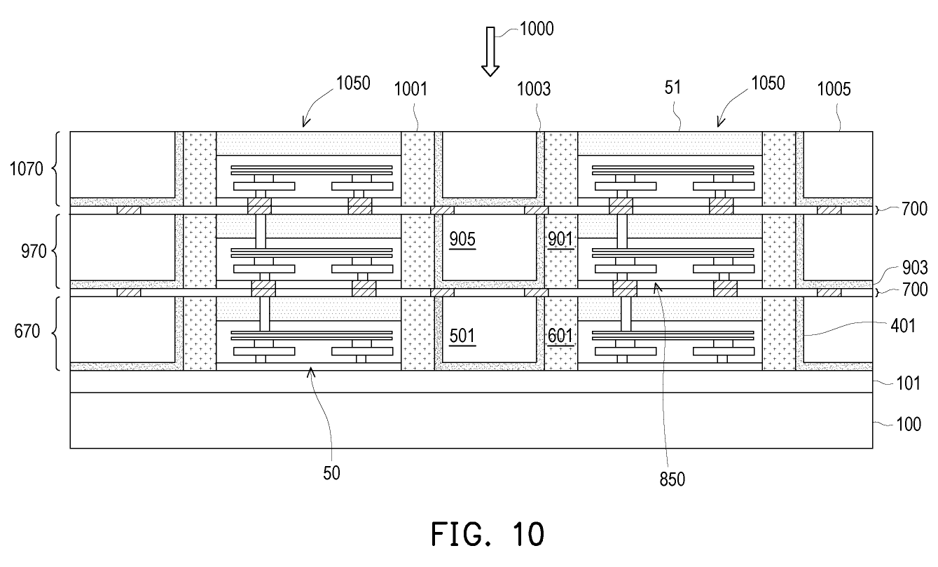

FIG. 10 illustrates a cross sectional view of a formation of a first top device layer 1070 formed over the first middle device layer 970 in accordance with some embodiments. In an embodiment, the first top device layer 1070 comprises a third integrated circuit die 1050 substantially similar to the first integrated circuit die 50, with the exception that the third integrated circuit die 1050 may omit the formation of the TSVs 59 within the third integrated circuit die 1050. In an embodiment, the first top device layer 1070 comprises a third buffer structure 1001, a third barrier layer 1003, and a third gapfill material 1005 processed with a third planarization process 1000.

In an embodiment, the formation of the first top device layer 1070 may be formed in a substantially similar manner as previously discussed with respect to the first middle device layer 970, however during the third planarization process 1000 planarization of the third integrated circuit die 1050 may not expose the TSVs 59 if the TSVs 59 were not formed in the third integrated circuit dies 1050 or if the first semiconductor substrate 51 of the third integrated circuit die 1050 is not thinned. It should be again noted that while FIG. 10 illustrates only one of the first middle device layer 970 beneath the first top device layer 1070, any number of the first middle device layer 970 may be formed prior to forming the first top device layer 1070. In certain embodiments, the first middle device layer 970 may be omitted entirely.

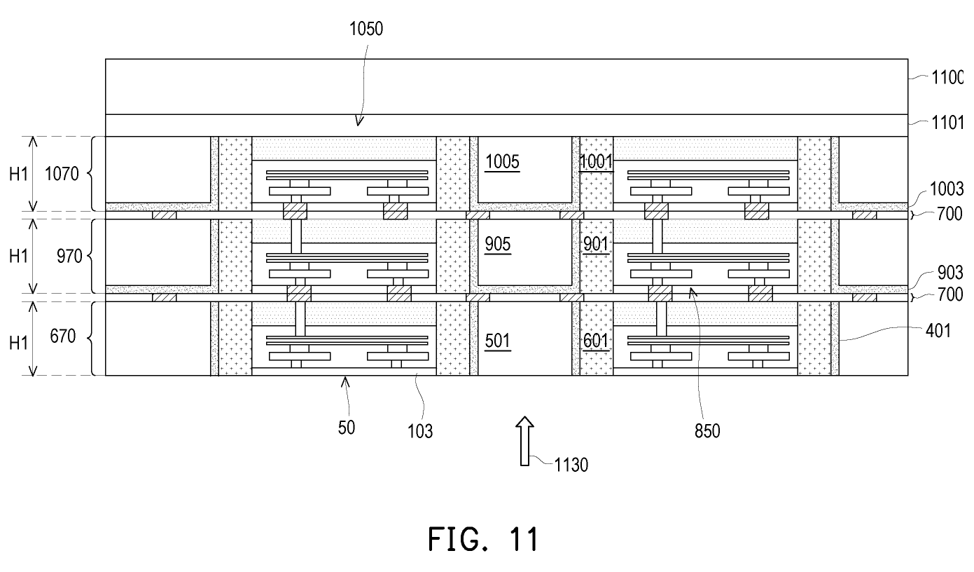

FIG. 11 illustrates a cross-sectional view of a second carrier substrate 1100 attached to the first top device layer 1070 to facilitate the removal of the first carrier substrate 100 in accordance with some embodiments. In an embodiment, the second carrier substrate 1100 may be attached to the first top device layer 1070 through an attachment layer 1101. In an embodiment, the attachment layer 1101 may be a bonding layer bonded to dielectric material (e.g., the third gapfill material 1005 or a separately deposited oxide layer over the third gapfill material 1005) through a dielectric-to-dielectric bond (e.g., an oxide-to-oxide bond). In another embodiment, the attachment layer 1101 may be an attachment film (e.g., an adhesive, a die attach film (DAF), or the like) utilized to attach the second carrier substrate 1100 to the first top device layer 1070.

In an embodiment, following the attachment of the second carrier substrate 1100 to the first top device layer 1070 a fourth planarization process 1130 may be performed to remove the first carrier substrate 100. In some embodiments, the fourth planarization process 1130 may be a CMP planarization process, an etch back process, combinations thereof, or the like. However any suitable planarization process may be utilized. Further, in accordance with some embodiments, the fourth planarization process 1130 further removes the first bonding layer 101, removes a portion of the first buffer structure 601, thins a portion of the second bonding layer 103, and removes a portion of the first barrier layer 401 along a major horizontal axis perpendicular to the first middle device layer 970. In another embodiment, the fourth planarization process removes the first carrier substrate 100, removes the first bonding layer 101, thins the first barrier layer 401, and thins the second bonding layer 103.

In an embodiment, the second carrier substrate 1100 provide structural support during the fourth planarization process 1130. Following the fourth planarization process 1130, the first barrier layer 401, the first gapfill material 501, the first buffer structure 601 and the first integrated circuit dies 50 (including the second bonding layer 103) share a first planar bottom surface. Further, in an embodiment, the first buffer structure 601 may have a first height H1 in a range between 15 microns to 30 microns (e.g., where a height of the first integrated circuit die 50, including the second bonding layer 103, is in a range of 15 microns to 30 microns). However, the first height of the first buffer structure 601 may be whatever height suitable to match the height of the first integrated circuit die 50. Further, in some embodiments, the second buffer structure 901 and the third buffer structure 1001 may also have the first height H1. In an embodiment, the first height H1 for each buffer structure may be at least the height of the corresponding integrated circuit die (e.g., the first integrated circuit dies 50, the second integrated circuit dies 850, and the third integrated circuit dies 1050). If any of the buffer structures have a height less than the first height H1 (e.g., a height less than the corresponding integrated circuit dies) than structures subsequently formed may apply strain to other structures (e.g., the corresponding integrated circuit dies) before making contact with the buffer structure potentially increasing the risk of corner crack propagation or non-bond risk at the corner of the associated integrated circuit die. If any of the buffer structures have a height greater than the first height H1 (e.g., a height greater than the corresponding integrated circuit dies) than structures subsequently formed may apply too much stain on the buffer structures causing the buffer structures to deform.

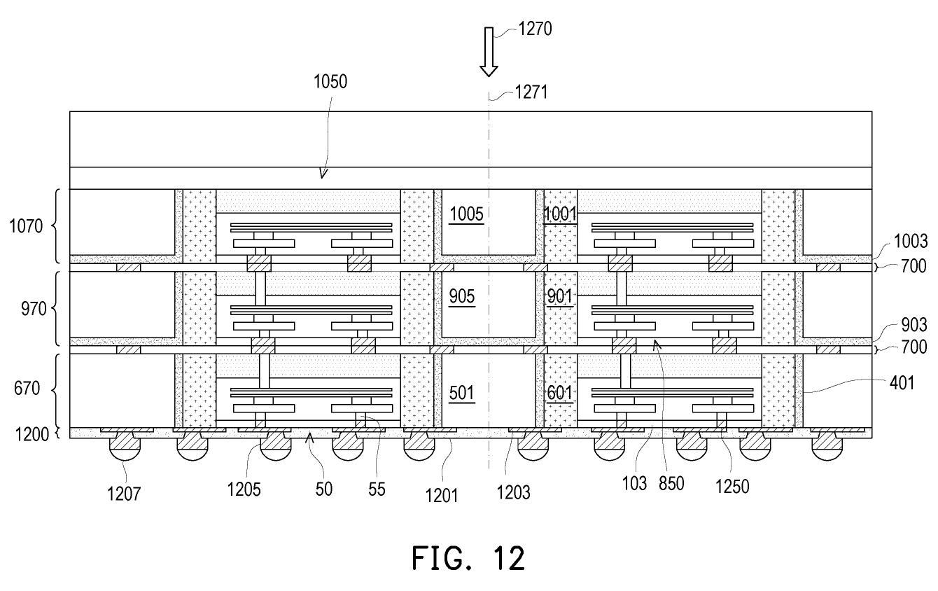

FIG. 12 illustrates a cross-sectional view of a formation of a redistribution structure 1200 over the first planar bottom surface of the first bottom device layer 670. In an embodiment, the redistribution structure 1200 is formed on an opposite side of the first planar bottom surface from the first integrated circuit dies 50. Further, FIG. 12 additionally illustrates die connectors 1250 formed through the second bonding layer 103 of the first integrated circuit dies 50 that allows for physical and electrical coupling of the redistribution structure 1200 to the first integrated circuit dies 50. In accordance with some embodiments, the redistribution structure 1200 is electrically coupled to the first integrated circuit dies 50, the second integrated circuit dies 850, and the third integrated circuit dies 1050.

In an embodiment, openings (not separately illustrated) are formed through the thinned portion of the second bonding layer 103 exposing the first metallization patterns 55 within the first integrated circuit dies 50. The die connectors 1250, such as conductive pillars (for example, formed of a metal such as copper), extend through the openings in the second bonding layer 103 and are physically and electrically coupled to the first metallization patterns 55 within the first integrated circuit dies 50. The die connectors 1250 may be formed by, for example, plating, or the like.

Further, in an embodiment, the redistribution structure 1200 includes a redistribution dielectric layer 1201, and a redistribution metallization pattern 1203. The redistribution metallization pattern 1203 may also be referred to as redistribution layer or redistribution line. The redistribution structure 1200 is shown as an example having one layer of metallization patterns. More dielectric layers and metallization patterns may be formed in the redistribution structure 1200. If more dielectric layers and metallization patterns are to be formed, steps and processes discussed below may be repeated. In some embodiments, the redistribution structure 1200 may be omitted entirely.

In an embodiment, the redistribution metallization pattern 1203 is then formed. The redistribution metallization pattern 1203 includes conductive elements extending along the major surface of the first planar bottom surface to physically and electrically couple to the die connectors 1250. As an example to form the redistribution metallization pattern 1203, a seed layer is formed over the first planar bottom surface of the first bottom device layer 670. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the redistribution metallization pattern 1203. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the redistribution metallization pattern 1203. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

In an embodiment, the redistribution dielectric layer 1201 is deposited over the redistribution metallization pattern 1203 and along the first planar bottom surface. In some embodiments, the redistribution dielectric layer 1201 is formed of a photo-sensitive material such as PBO, polyimide, BCB, or the like, which may be patterned using a lithography mask. The redistribution dielectric layer 1201 may be formed by spin coating, lamination, CVD, the like, or a combination thereof. The redistribution dielectric layer 1201 is then patterned. The patterning forms openings exposing portions of the redistribution metallization patterns 1203. The patterning may be by an acceptable process, such as by exposing and developing the redistribution dielectric layer 1201 to light when the redistribution dielectric layer 1201 is a photo-sensitive material or by etching using, for example, an anisotropic etch.

Following the patterning of the redistribution dielectric layer 1201, under bump metallizations (UBMs) 1205 are formed for external connection to the redistribution structure 1200 and the overlying integrated circuit dies 50, 850, and 1050. The UBMs 1205 have bump portions on and extending along the major surface of the redistribution dielectric layer 1201, and have via portions extending through the redistribution dielectric layer 1201 to physically and electrically couple the redistribution metallization pattern 1203. As a result, the UBMs 1205 are electrically coupled to the first integrated circuit dies 50. The UBMs 1205 may be formed of the same material as the redistribution metallization pattern 1203. In some embodiments, the UBMs 1205 have a different size than the redistribution metallization pattern 1203.

Further, in an embodiment, conductive connectors 1207 are formed on the UBMs 1205. The conductive connectors 1207 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 1207 may include a conductive material such as solder, copper, aluminum, gold, nickel, silver, palladium, tin, the like, or a combination thereof. In some embodiments, the conductive connectors 1207 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 1207 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Further, in an embodiment, a singulation process 1270 may be performed along scribe lines 1271 in the associated first bottom device layer 670, the associated first middle device layer 970, and the associated first top device layer 1070 may be packaged in subsequent processing to form an integrated circuit package (not separately illustrated). In accordance with some embodiments, the singulation process may be a sawing process, however any suitable singulation process may be utilized. Additionally, in some embodiments, the second carrier substrate 1100 may also be optionally removed.

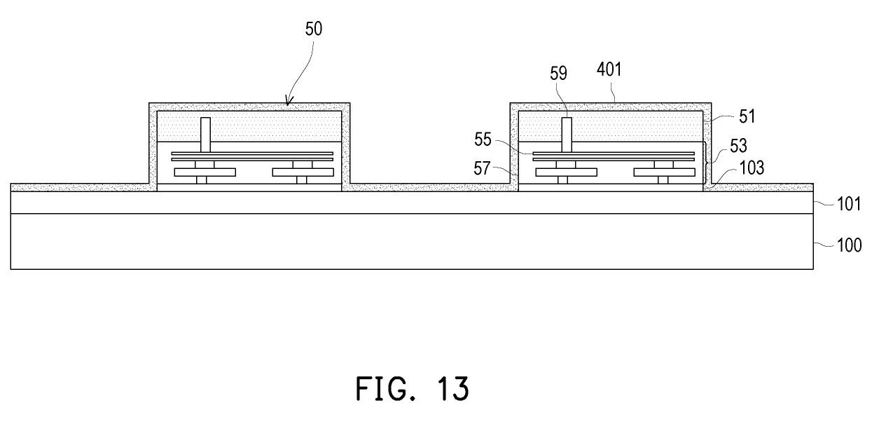

FIGS. 13-23 illustrate another embodiment in which barrier layers are deposited directly over integrated circuit dies prior to the formation of buffer structures such that the buffer structures are disposed between gap filler materials and the barrier layers. In FIGS. 13-23, like reference numerals indicate like elements formed by like processes as FIGS. 1-12 unless otherwise noted.

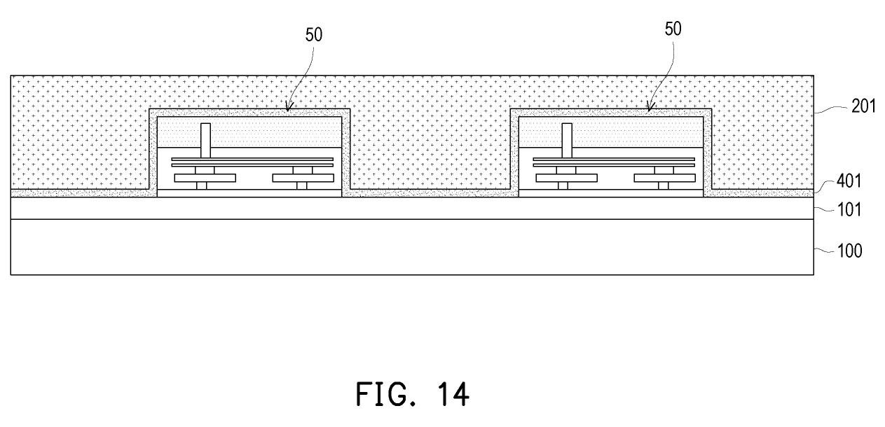

FIG. 13 illustrates a cross-sectional view in which one or more of the first integrated circuit dies 50 are bonded to the first carrier substrate 100 as well as the deposition of the first barrier layer 401. In an embodiment, the bonding of the one or more first integrated circuit dies 50 to the first carrier substrate 100 may be performed in a similar manner as discussed above with respect to FIG. 1. In an embodiment, following the bonding of the one or more first integrated circuit dies 50 to the first carrier substrate 100, the first barrier layer 401 may be formed over the one or more first integrated circuit dies 50 as well as the first bonding layer 101 of the first carrier substrate 100. In an embodiment, the formation of the first barrier layer 401 may be performed in a similar manner with similar materials as discussed above with respect to FIG. 4 with the exception that the first barrier layer 401 is formed before the formation of the first buffer material 201 (see FIG. 14). It should be noted that structures illustrated in FIG. 13, such as the first integrated circuit dies 50, may include similar components and formed of similar materials in similar processes as previously discussed above.

FIG. 14 illustrates a cross-sectional view in which the first buffer material 201 is formed over the first barrier layer 401. In this embodiment, the first buffer material 201 may be formed from similar materials and in a similar manner as discussed above with respect to FIG. 2 with the exception that the first buffer material 201 is formed over and in direct contact with the first barrier layer 401. In an embodiment, the first buffer material 201 may comprise a polymer such as, a photosensitive polymer, a polyimide, or the like. In an embodiment, the first buffer material 201 may comprise HD4100, HD8820, Fuji LTC9320-E07, Toray LT-S8300A, HD7100, Asahi BL301, Benzocyclobutene (BCB) base material, Polybenzoxazoles(PBO) base material, the like, or a combination thereof. In accordance with some embodiments, the first buffer material 201 may have the first toughness. If the first buffer material 201 has a toughness less than the first toughness than the first buffer material 201 may be too brittle and have an inadequate risk of crack propagation. If the first buffer material 201 has a toughness greater than the first toughness than the first buffer material 201 may not be rigid enough to provide adequate support for subsequent processing steps performed over the first buffer material 201.

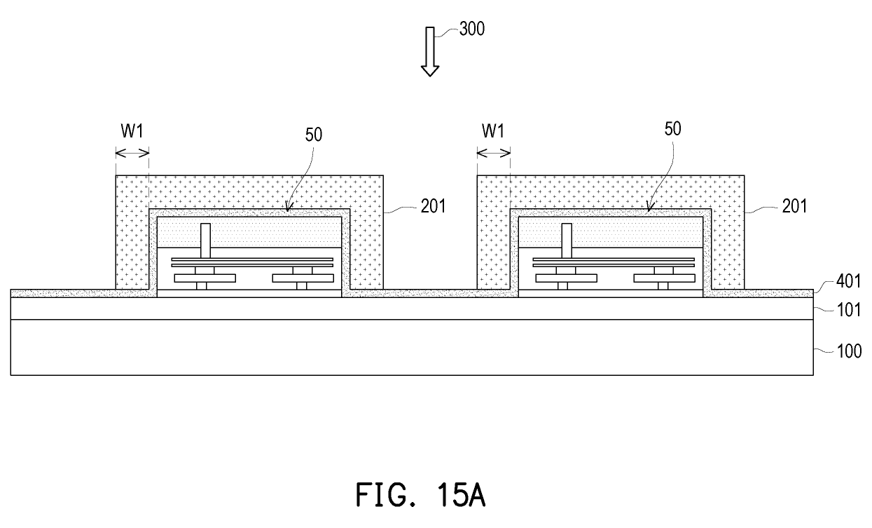

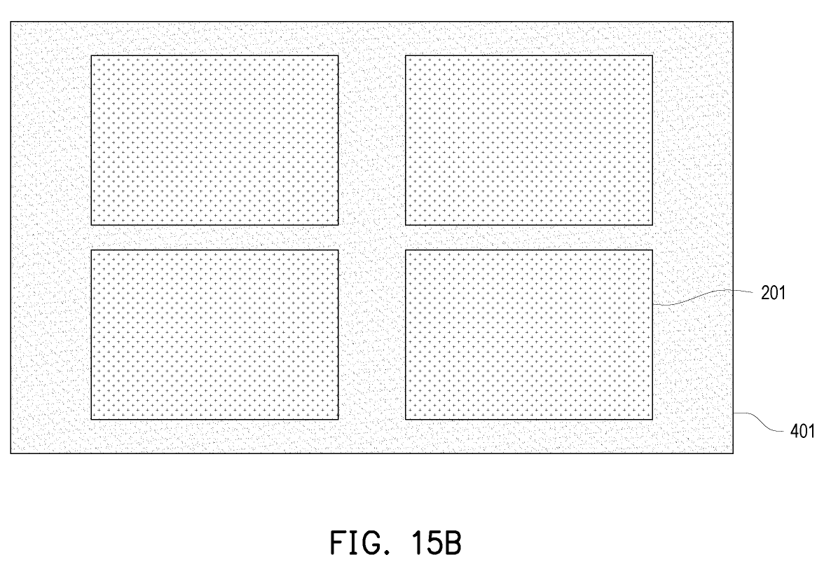

FIG. 15A illustrates a cross-sectional view of the patterning process 300 of the first buffer material 201 to remove excess portions of the first buffer material 201 around the one or more first integrated circuit dies 50 over the first carrier substrate 100. In an embodiment the patterning process 300 of the first buffer material 201 may be performed in a similar manner as discussed above with respect to FIG. 3. The first width W1 of the first buffer material 201 may be measured from sidewalls of the first barrier layer 401 to an exterior sidewall of the first buffer material 201.

FIG. 15B illustrates a top-down plan view following the patterning process 300 of the first buffer material 201. In an embodiment, following the patterning process 300, the first barrier layer 401 covers a top surface of the first integrated circuit dies 50 (not illustrated in FIG. 15B) and the major surface of the first bonding layer 101 (not illustrated in FIG. 15B) not covered by the first integrated circuit dies 50. In this embodiment, the first buffer material 201 covers the top surface of the first barrier layer 401 covering the first integrated circuit dies 50. In an embodiment the first buffer material also covers a portion of the first barrier layer 401 over the first bonding layer 101 by the first width W1 extending from a side of the sidewalls of the first barrier layer 401 opposite a side of the first barrier layer 401 covering the first integrated circuit dies 50.

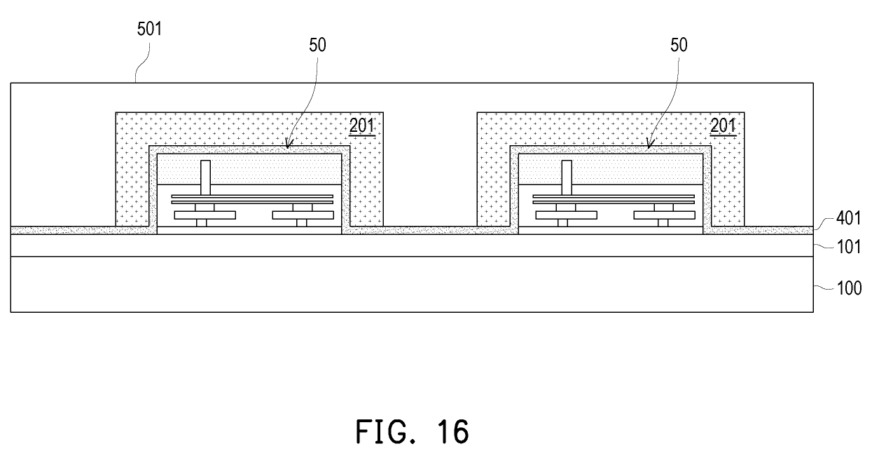

FIG. 16 illustrates a cross-sectional view of the first gapfill material 501 over the first buffer material 201 and exposed portions of the first barrier layer 401. In an embodiment the first gapfill material 501 may be formed of a similar material and in a similar manner as discussed above with respect to FIG. 5. In some embodiments, the first gapfill material 501 may also have a greater geometric stiffness than the first buffer material 201. In some embodiments, the geometric stiffness of the first gapfill material 501 provides structural stability for subsequent processing steps performed over the first gapfill material 501. In some embodiments, where the geometric stiffness of the first gapfill material 501 is greater than the geometric stiffness of the first buffer material 201 and the geometric stiffness of the first gapfill material 501 may help provide additional rigidity to compensate for the flexibility of the first buffer material 201.

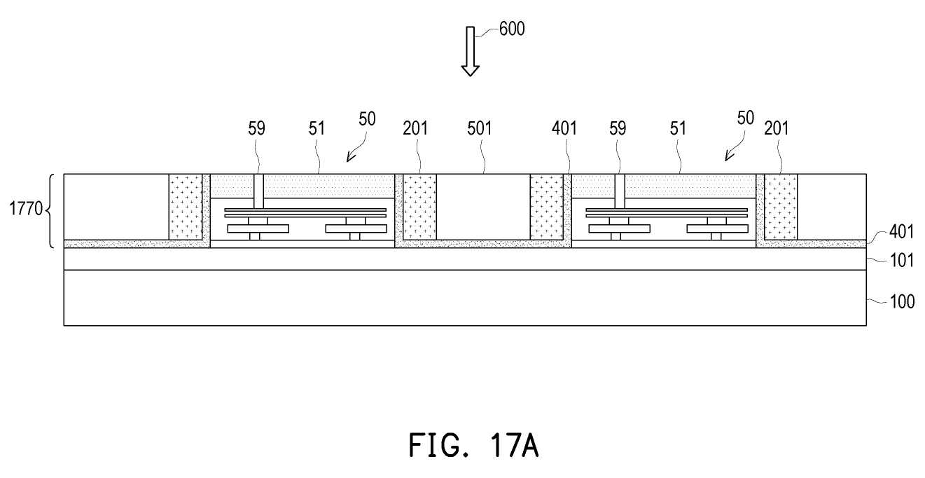

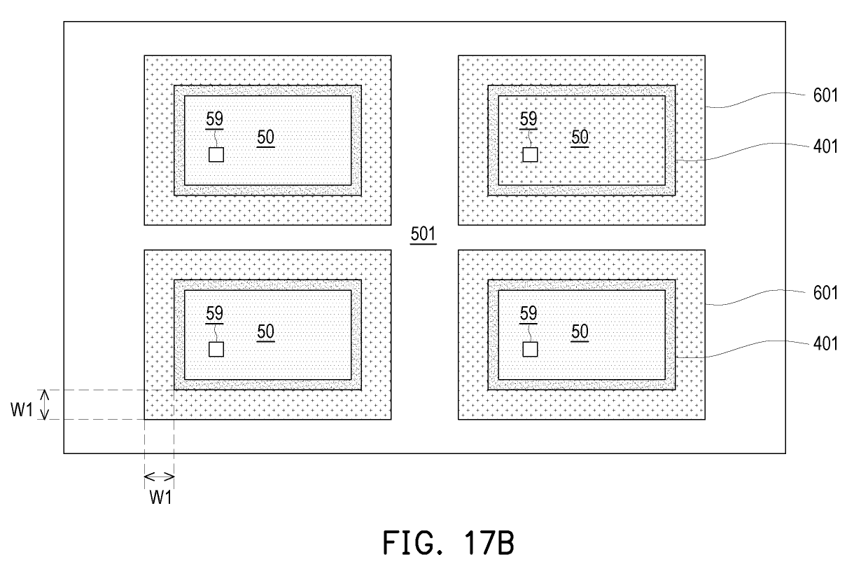

FIG. 17A illustrates a cross-sectional view the first planarization process 600 performed on the first gapfill material 501, the first barrier layer 401, the first buffer material 201 and the one or more first integrated circuit dies 50. In an embodiment, the first planarization process 600 is performed in a similar manner as discussed above with respect to FIG. 6A and results in top surfaces of the first gapfill material 501, the first barrier layer 401, and the resulting first buffer structure 601 being substantially planar. Further, the first planarization process 600 establishes a second bottom device layer 1770 upon which subsequent layers of integrated circuit dies and associated structures may be formed.

FIG. 17B illustrates a top-down plan view following the first planarization process 600 performed on the first gapfill material 501, the first barrier layer 401, the first buffer material 201 and the one or more first integrated circuit dies 50 resulting in the first buffer structure 601, all over the first carrier substrate 100 (not separately illustrated). In this embodiment, each of the first barrier layer 401 fully encircles each of the first integrated circuit dies 50, with each of the first barrier layers 401 being in direct physical contact with each of the first integrated circuit dies 50. The first buffer structures 601 then fully encircles each of the first barrier layers 401 encircling each of the one or more first integrated circuit dies 50. The first buffer structures 601 also each have the first width W1 extending from the sidewalls of the first barrier layer 401 opposite the first integrated circuit dies 50. The first gapfill material 501 fills remaining gaps between the different first integrated circuit dies 50 and the associated first buffer structures 601 and the associated first barrier layer 401.

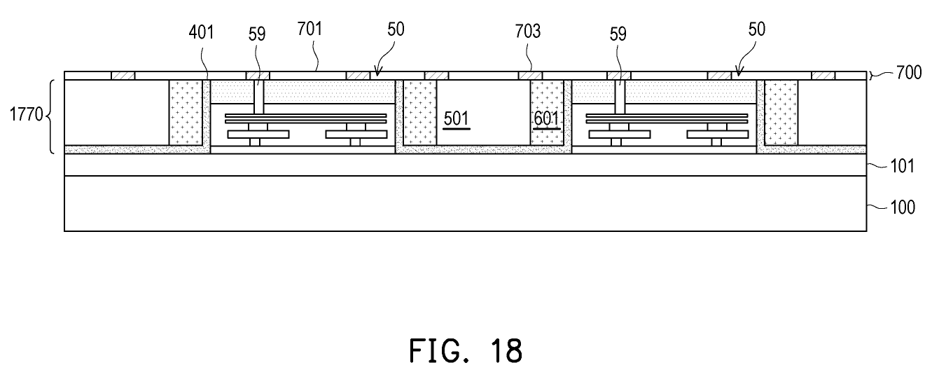

FIG. 18 illustrates a cross-sectional view of the formation of the third bonding layer 700 over the first planar top surface of the second bottom device layer 1770. In an embodiment the third bonding layer 700 may comprise the first dielectric layer 701 and the first bond pads 703 embedded within the first dielectric layer 701. In this embodiment, the first dielectric layer 701 and the first bond pads 703 may be formed from similar materials and in a similar manner as discussed above with respect to FIG. 7.

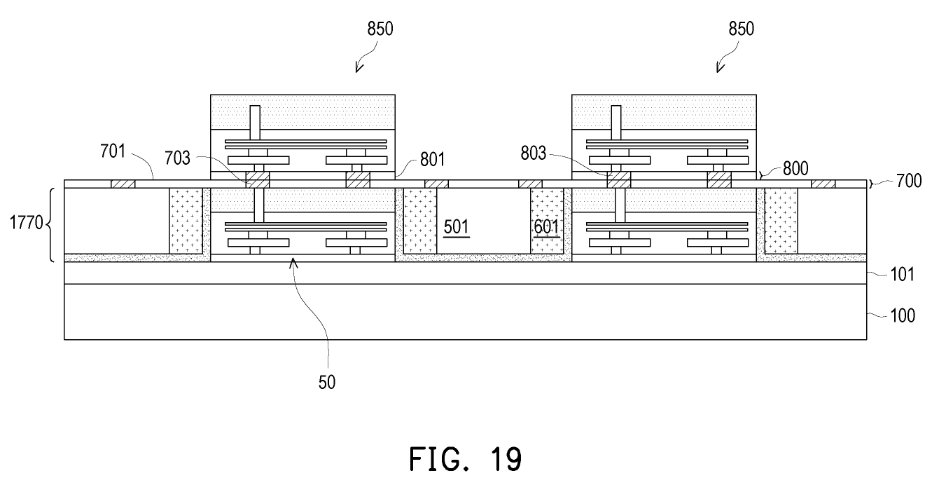

FIG. 19 illustrates a cross-sectional view of the bonding of the second integrated circuit dies 850 to the third bonding layer 700. In an embodiment, the second integrated circuit dies 850 may be substantially similar to the first integrated circuit dies 50. In some embodiments, the fourth bonding layer 800 is formed over the active side/front side of the second integrated circuit die 850. The fourth bonding layer 800 may comprise the second dielectric layer 801 and the second bond pads 803 embedded within the second dielectric layer 801. In an embodiment, the second dielectric layer 801 and the second bond pads 803 may be formed of similar materials and in a similar manner as the first dielectric layer 701 and the first bond pads 703 respectively. In an embodiment, the second integrated circuit dies 850 may be bonded to the second bottom device layer 1770 in a similar manner resulting in similar features as discussed above with respect to FIG. 8.

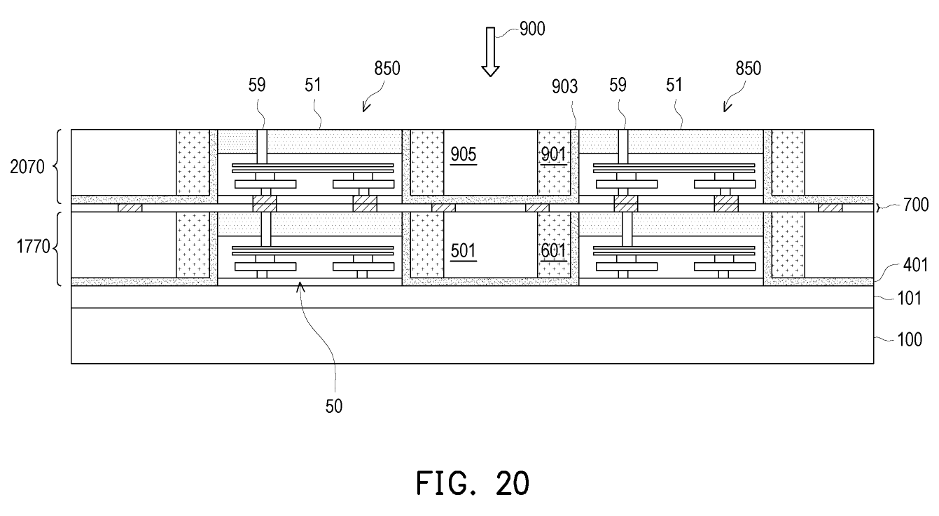

FIG. 20 illustrates a cross-sectional view of the formation of the second buffer structure 901, the second barrier layer 903 and the second gapfill material 905 encircling the second integrated circuit dies 850. In accordance with some embodiments, following the formation of the second buffer structure 901, the second barrier layer 903, and the second gapfill material 905 the second planarization process 900 may be performed. In an embodiment, the formation of the second buffer structure 901, the second barrier layer 903 and the second gapfill material 905, as well as the second planarization process 900 may be processed in a substantially similar manner as previously discussed with respect to the first buffer structure 601, the first barrier layer 401, the first gapfill material 501, and the first planarization process 600 as discussed with respect to FIGS. 13-17B. Further, it should be noted that a cycle forming a second middle device layer 2070 may be repeated as many times as suitable for forming a desired number of the stacked device layers.

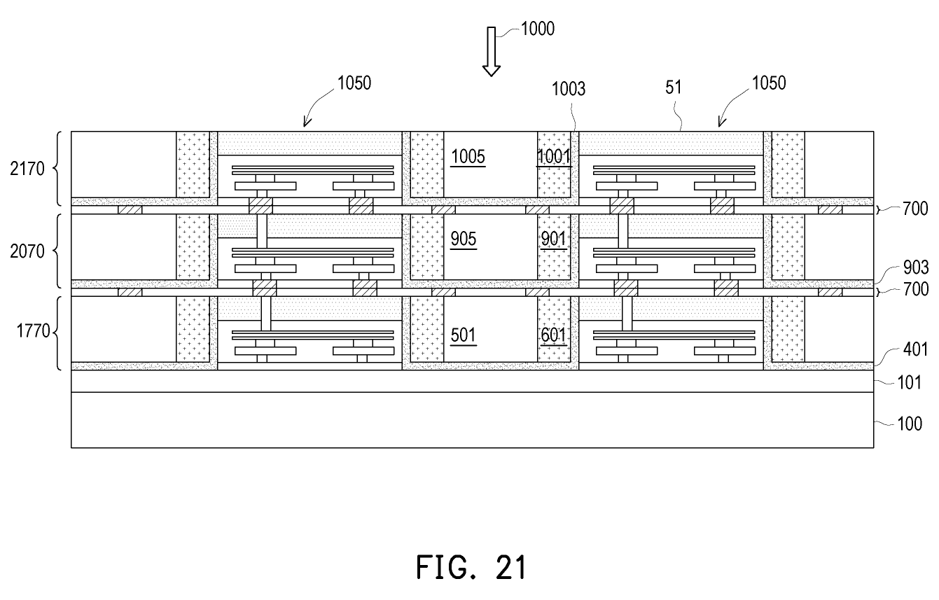

FIG. 21 illustrates a cross-sectional view of the formation of a second top device layer 2170 formed over the second middle device layer 2070. In an embodiment, the second top device layer 2170 comprises the third integrated circuit die 1050 substantially similar to the first integrated circuit die 50, with the exception that the third integrated circuit die 1050 may omit the formation of the TSVs 59 within the third integrated circuit die 1050. Further, the first top device layer 1070 comprises the third buffer structure 1001, the third barrier layer 1003, and the third gapfill material 1005 processed with the third planarization process 1000. The formation of the first top device layer 1070 may be formed in a substantially similar manner as previously discussed with respect to the second middle device layer 2070 in FIGS. 13-20, and in a similar manner as the formation of the first top device layer 1070.

Further, in an embodiment, the first buffer structure 601 may have the first height H1 in a range between 15 microns to 30 microns (e.g., where a height of the first integrated circuit die 50, including the second bonding layer 103, is in a range of 15 microns to 30 microns). However, the first height H1 of the first buffer structure 601, the second buffer structure 901, and the third buffer structure 1001 may be a height such that the top surface of the buffer structures is planar with the top surface of the corresponding integrated circuit die. In an embodiment, the first height H1 for each buffer structure may be at least the height of the corresponding integrated circuit die (e.g., the first integrated circuit dies 50, the second integrated circuit dies 850, and the third integrated circuit dies 1050) taking into account that the buffer structures may be formed over a barrier layer. If any of the buffer structures have a height less than the first height H1 (e.g., a height less than the corresponding integrated circuit dies) than structures subsequently formed may apply strain to other structures (e.g., the corresponding integrated circuit dies) before making contact with the buffer structure potentially increasing the risk of corner crack propagation or non-bond risk at the corner of the associated integrated circuit die. If any of the buffer structures have a height greater than the first height H1 (e.g., a height greater than the corresponding integrated circuit dies) than structures subsequently formed may apply too much stain on the buffer structures causing the buffer structures to deform.

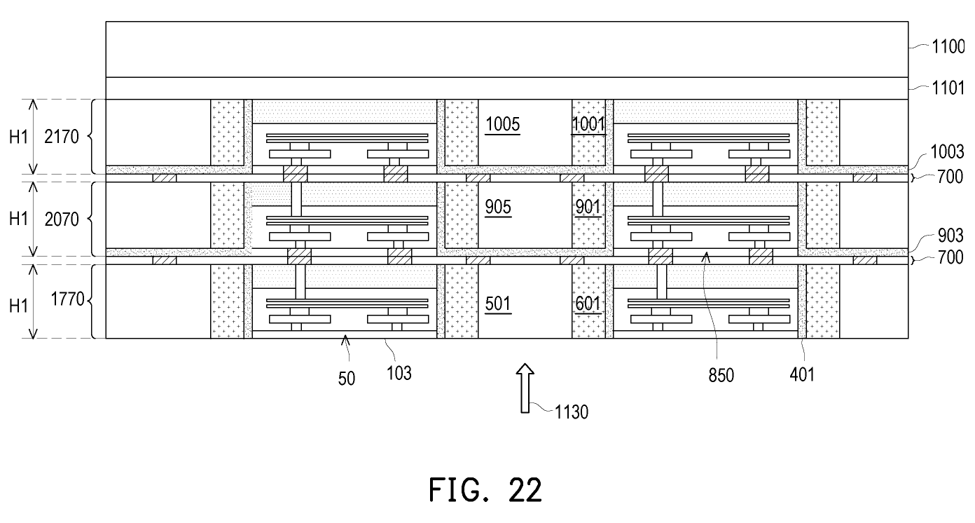

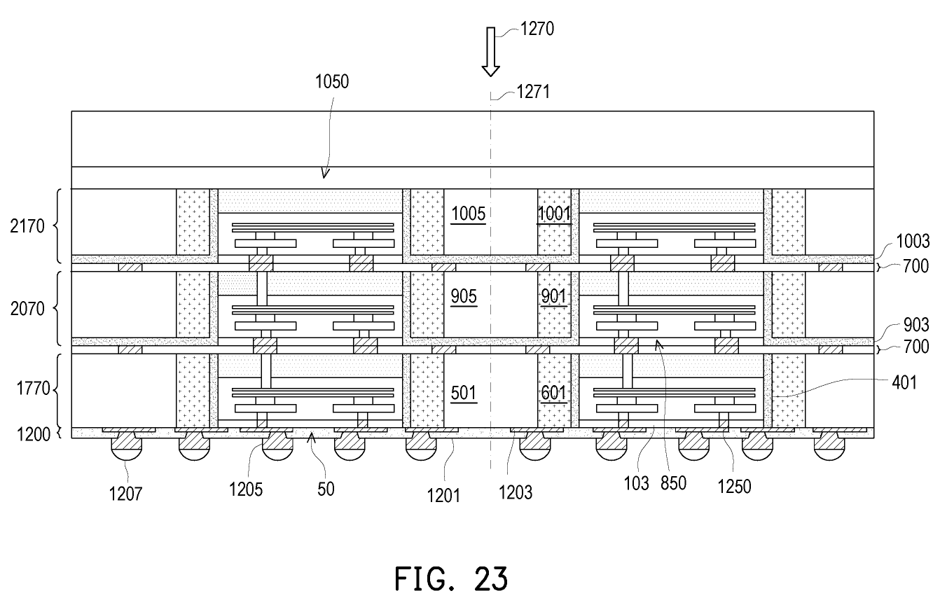

FIG. 22 illustrates a cross-sectional view of the second carrier substrate 1100 attached to the second top device layer 2170 to facilitate the removal of the first carrier substrate 100. In an embodiment, the second carrier substrate 1100 may be attached in a similar manner as discussed previously with respect to FIG. 11. FIG. 23 additionally illustrates the fourth planarization process 1130 in a similar manner as previously discussed with respect to FIG. 11.

FIG. 23 illustrates a cross-sectional view of the formation of the redistribution structure 1200 over the first planar bottom surface of the second bottom device layer 1770 along with the formation of the die connectors 1250. In an embodiment, the formation of the die connectors 1250 may be formed of similar materials and in a similar manner as previously discussed with respect to FIG. 12A. In an embodiment, the redistribution structure 1200 includes the redistribution dielectric layer 1201, and the redistribution metallization pattern 1203 which may be formed from similar materials and in a similar manner as previously discussed with respect to FIG. 12A. In an embodiment, the UBMs 1205 and the conductive connectors 1207 may be formed of similar materials and in a similar manner as previously discussed with respect to FIG. 12.

Further, in an embodiment, the singulation process 1270 may be performed along the scribe lines 1271 and each of the integrated circuit dies in the associated second bottom device layer 1770, the associated second middle device layer 2070, and the associated second top device layer 2170 may be packaged in subsequent processing to form an integrated circuit package (not separately illustrated) in a similar manner as discussed previously with respect to FIG. 12. In accordance with some embodiments, the singulation process 1270 may be a sawing process, however any suitable singulation process may be utilized. Additionally, in some embodiments, the second carrier substrate 1100 may also be optionally removed.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. In accordance with some embodiments the inclusion of the first buffer structure 601 may allow for the absorption of stress that may be caused by strain from additionally added semiconductor dies (e.g., the second integrated circuit die 850) over another semiconductor dies (e.g., the first integrated circuit die 50) surrounded by the first buffer structure 601. The stress reduced from the inclusion of the first buffer structure 601 may additionally reduce the risk of non-bonding at the corner of the die during smiling die fabrication. Additional buffer structures surrounding overlaying dies (e.g., the second buffer structure 901 surrounding the second integrated circuit die 850) may additionally help reduce the risk of stress on subsequently stacked dies (e.g., the third integrated circuit die 1050). The absorption of stress resulting from the inclusion of the buffer structures may help improve manufacturing integrity and device functionality.

In accordance with an embodiment, a semiconductor device including a first semiconductor die, an oxide layer on the first semiconductor die, wherein the first semiconductor die has a first top surface opposite the oxide layer, a first insulating material encapsulating the first semiconductor die and the oxide layer, wherein the first insulating material has a second top surface planar with the first top surface, and a first polymer buffer disposed between a sidewall of the first semiconductor die and a sidewall of the first insulating material, wherein the first polymer buffer has a third top surface planar with both the first top surface and the second top surface. In an embodiment further including a silicon nitride layer disposed between the sidewall of the first semiconductor die and the sidewall of the first polymer buffer, wherein the silicon nitride layer has a fourth top surface planar with both the first top surface and the third top surface. In an embodiment further including a silicon nitride layer disposed between the sidewall of the first insulating material and sidewalls of the first polymer buffer, wherein the silicon nitride layer has a fourth top surface planar with both the second top surface and the third top surface. In an embodiment wherein the first polymer buffer has a first width, the first width being in a range of 1 microns to 30 microns. In an embodiment wherein the first polymer buffer includes a polyimide having a first toughness, and wherein the first insulating material comprises an oxide having a second toughness less than the first toughness. In an embodiment further including a first bonding layer over the first top surface, the second top surface and the third top surface, a second bonding layer bonded to the first bonding layer with metal-to-metal and dielectric-to-dielectric bonds, a second semiconductor die over the second bonding layer, a second insulating material encapsulating the second semiconductor die, and a second polymer buffer between a sidewall of the second insulating material and a sidewall of the second semiconductor die. In an embodiment further including conductive features within the oxide layer, and a redistribution structure over the oxide layer opposite the first semiconductor die, wherein the redistribution structure is electrically coupled to the first semiconductor die through the conductive features.

In accordance with an embodiment, a method of manufacturing a semiconductor device includes forming a dielectric-to-dielectric bond between a first oxide layer of a first semiconductor die and a second oxide layer of a carrier substrate, spin coating a photosensitive polymer over the carrier substrate, the photosensitive polymer covering the first semiconductor die, patterning the photosensitive polymer to form a buffer layer from the photosensitive polymer, wherein the buffer layer encompasses the first semiconductor die, depositing an oxide material over the buffer layer, and performing a first planarization process on the oxide material and the buffer layer to expose the first semiconductor die, wherein after the planarization process the first semiconductor die, the buffer layer, and the oxide material share a planar top surface. In an embodiment further including performing a second planarization process, wherein the second planarization process removes the carrier substrate and a portion of the first oxide layer. In an embodiment further including bonding a second semiconductor die to the planar top surface, wherein the second semiconductor die is electrically coupled to the first semiconductor die. In an embodiment further including attaching a support substrate over the second semiconductor die opposite the first semiconductor die. In an embodiment further including depositing a silicon nitride layer over the carrier substrate and along sidewalls of the first semiconductor die before the spin coating the photosensitive polymer. In an embodiment further including depositing a silicon nitride layer over the carrier substrate and along sidewalls of the buffer layer before the depositing the oxide material. In an embodiment wherein the buffer layer has a first toughness greater than a second toughness of the oxide material.

In accordance with an embodiment, a semiconductor device includes a first semiconductor die, a first polymer buffer encircling the first semiconductor die, and a first insulating layer encircling the first polymer buffer, wherein the first polymer buffer extends along a sidewall of the first semiconductor die from a level of a first planar top surface of the first semiconductor die to a level of a bottom surface of the first semiconductor die. In an embodiment further including a second semiconductor die bonded to the first semiconductor die, a second polymer buffer encircling the second semiconductor die, and a second insulating layer encircling the second polymer buffer, wherein the second insulating, the second polymer buffer, and the second semiconductor die share a second planar top surface, the second planar top surface being parallel to the first planar top surface. In an embodiment wherein the first polymer buffer includes a photosensitive polyimide. In an embodiment wherein the first polymer buffer is less brittle than the first insulating layer. In an embodiment further including a silicon nitride layer disposed between the first polymer buffer and the first insulating layer, wherein the silicon nitride layer encircles the first semiconductor die. In an embodiment further including a silicon nitride layer disposed between the first semiconductor die and the first polymer buffer, wherein the silicon nitride layer encircles the first semiconductor die.

In one general aspect, embodiments disclosed herein may include forming a dielectric-to-dielectric bond between a first oxide layer of a first semiconductor die and a second oxide layer of a carrier substrate. The method may also include spin coating a photosensitive polymer over the carrier substrate, the photosensitive polymer covering the first semiconductor die. The method may furthermore include patterning the photosensitive polymer to form a buffer layer from the photosensitive polymer, where the buffer layer encompasses the first semiconductor die. The method may in addition include depositing an oxide material over the buffer layer. The method may moreover include performing a first planarization process on the oxide material and the buffer layer to expose the first semiconductor die, where after the first planarization process the first semiconductor die, the buffer layer, and the oxide material share a planar top surface

In another general aspect, embodiments disclosed herein may include attaching a front side of a first semiconductor device to a carrier. The method may also include attaching a front side of a second semiconductor device to the, where the second semiconductor device is laterally spaced apart from the first semiconductor device to form a gap between the first semiconductor device and the second semiconductor device. The method may furthermore include partially filling the gap with a buffer layer and a barrier layer to form a partially-filled gap. The method may in addition include filling the partially-filled gap with a gap fill layer to form a filled-gap. The method may moreover include forming a bonding layer over the first semiconductor device, the second semiconductor device, and the filled-gap; bonding a third semiconductor device to the first semiconductor device through the bonding layer and bonding a fourth semiconductor device to the second semiconductor device through the bonding layer. The method may also include separating the first and third semiconductor devices from the second and fourth semiconductor devices.

In yet general aspect, embodiments disclosed herein may include provisioning a plurality of first semiconductor devices on a plane, where adjacent ones of the first semiconductor devices are separated by respective gaps. The method may also include partially filling the respective gaps with a buffer layer and a barrier layer to form a respective partially-filled gaps. The method may furthermore include filling the respective partially-filled gaps with a gap fill layer to form a respective filled gaps. The method may in addition include bonding respective ones of a plurality of second semiconductor devices to respective ones of the plurality of first semiconductor devices in a face-to-back configuration to form a plurality of stacked devices, where adjacent ones of the second semiconductor devices are separated by respective second gaps. The method may moreover include partially filling the respective second gaps with a buffer layer and a barrier layer to form respective partially-filled gaps. The method may also include filling the respective partially-filled gaps with a gap fill layer to form respective filled gaps. The method may furthermore include singulating the plurality of stacked devices into individual stacks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a dielectric-to-dielectric bond between a first oxide layer of a first semiconductor die and a second oxide layer of a carrier substrate;
spin coating a photosensitive polymer over the carrier substrate, the photosensitive polymer covering the first semiconductor die;
patterning the photosensitive polymer to form a buffer layer from the photosensitive polymer, wherein the buffer layer encompasses the first semiconductor die;
depositing an oxide material over the buffer layer; and
performing a first planarization process on the oxide material and the buffer layer to expose the first semiconductor die, wherein after the first planarization process the first semiconductor die, the buffer layer, and the oxide material share a planar top surface.

2. The method of claim 1, further comprising performing a second planarization process, wherein the second planarization process removes the carrier substrate and a portion of the first oxide layer.

3. The method of claim 1, further comprising bonding a second semiconductor die to the planar top surface, wherein the second semiconductor die is electrically coupled to the first semiconductor die.

4. The method of claim 3, further comprising attaching a support substrate over the second semiconductor die opposite the first semiconductor die.

5. The method of claim 1, further comprising depositing a silicon nitride layer over the carrier substrate and along sidewalls of the first semiconductor die before the spin coating the photosensitive polymer.

6. The method of claim 1, further comprising depositing a silicon nitride layer over the carrier substrate and along sidewalls of the buffer layer before the depositing the oxide material.

7. The method of claim 1, wherein the buffer layer has a first toughness greater than a second toughness of the oxide material.

8. A method comprising:
attaching a front side of a first semiconductor device to a carrier;
attaching a front side of a second semiconductor device to the carrier, wherein the second semiconductor device is laterally spaced apart from the first semiconductor device to form a gap between the first semiconductor device and the second semiconductor device;
partially filling the gap with a buffer layer and a barrier layer to form a partially-filled gap;
filling the partially-filled gap with a gap fill layer to form a filled-gap;
forming a bonding layer over the first semiconductor device, the second semiconductor device, and the filled-gap;
bonding a third semiconductor device to the first semiconductor device through the bonding layer and bonding a fourth semiconductor device to the second semiconductor device through the bonding layer; and
separating the first and third semiconductor devices from the second and fourth semiconductor devices.

9. The method of claim 8, wherein the step of partially filling the gap with the buffer layer and the barrier layer to form the partially-filled gap includes:
depositing the buffer layer on the first semiconductor device and the second semiconductor device and within the gap;
patterning the buffer layer to form a patterned buffer layer; and
depositing the barrier layer on the patterned buffer layer.

10. The method of claim 8, wherein the step of partially filling the gap with the buffer layer and the barrier layer to form the partially-filled gap includes:
depositing the barrier layer on the first semiconductor device and the second semiconductor device and within the gap;
depositing the buffer layer on the barrier layer; and
patterning the buffer layer.

11. The method of claim 8, wherein the step of separating the first and third semiconductor devices from the second and fourth semiconductor devices includes sawing through the gap fill layer, the barrier layer, and the buffer layer in the filled-gap.

12. The method of claim 8, further comprising:
adhering a back side of the third semiconductor device and the fourth semiconductor device to a second carrier; and
forming a redistribution structure on the front side of the first semiconductor device and the second semiconductor device.

13. The method of claim 8, wherein the step of attaching a front side of a first semiconductor device to a carrier includes using a dielectric-to-dielectric bonding process.

14. The method of claim 8, further comprising planarizing the gap fill layer, the barrier layer, and the buffer layer to be coplanar with a back side of the first semiconductor device.

15. The method of claim 14, further comprising thinning the first semiconductor device from the back side of the first semiconductor device.

16. The method of claim 15, further comprising forming a through silicon via (TSV) extending partially through the first semiconductor device and wherein the step of thinning the first semiconductor device exposes the TSV.

17. A method comprising:
provisioning a plurality of first semiconductor devices on a plane, wherein adjacent ones of the first semiconductor devices are separated by respective gaps;
partially filling the respective gaps with a buffer layer and a barrier layer to form a respective partially-filled gaps;
filling the respective partially-filled gaps with a gap fill layer to form a respective filled gaps;
bonding respective ones of a plurality of second semiconductor devices to respective ones of the plurality of first semiconductor devices in a face-to-back configuration to form a plurality of stacked devices, wherein adjacent ones of the second semiconductor devices are separated by respective second gaps;
partially filling the respective second gaps with a buffer layer and a barrier layer to form respective partially-filled gaps;
filling the respective partially-filled gaps with a gap fill layer to form respective filled gaps; and
singulating the plurality of stacked devices into individual stacks.

18. The method of claim 17, wherein the step of singulating the plurality of stacked devices into individual stacks comprises sawing through the buffer layer, the barrier layer, and the gap fill layer.

19. The method of claim 18, wherein the buffer layer is configured to compensate for stress arising from manufacturing processes.

20. The method of claim 18, further comprising forming a bonding layer extending between the plurality of first semiconductor devices and the plurality of second semiconductor devices.
